(19) United States
(12) Patent Application Publication
(10) Pub. No.: US 2013/0320293 A1
(43) Pub. Date: Dec. 5, 2013

(54) SEMICONDUCTOR LIGHT EMITTING DEVICE PACKAGE AND METHOD OF MANUFACTURING THE SAME

(71) Applicant: Samsung Electronics Co., Ltd, Suwon-si (KR)

(72) Inventors: Jong Wan SEO, Hwaseong (KR); Hyung Kun KIM, Suwon (KR)

(73) Assignee: Samsung Electronics Co., Ltd, Suwon- (KR)

(21) Appl. No.: 13/908,151

(22) Filed: Jun. 3, 2013

(30) Foreign Application Priority Data
Jun. 4, 2012 (KR) 10-2012-0059936

(51) Int. Cl. H01L 33/36; H01L 33/50

(52) U.S. Cl. CPC H01L 33/36; H01L 33/50
USPC 257/9; 257/99; 438/22

(57) ABSTRACT

A semiconductor light emitting device package includes a base unit including a main body having electrical insulation properties and at least one pair of first and second through electrodes formed in the main body in a thickness direction thereof and formed of a semiconductor material, and a light emitting structure disposed on the base unit and including first and second conductivity type semiconductor layers and an active layer interposed there between. The manufacturing process thereof may be simplified, whereby a reduction in manufacturing costs and time may be achieved.

### CROSS-REFERENCE TO RELATED APPLICATIONS

This application claims the benefit of priority under 35 U.S.C. §119 from Korean Patent Application No. 10-2012-0059936 filed on Jun. 4, 2012, in the Korean Intellectual Property Office, the disclosure of which is incorporated herein by reference in its entirety.

### BACKGROUND

1. Field

The present general inventive concept relates to a semiconductor light emitting device package and a method of manufacturing the same.

2. Description of the Related Art

A semiconductor light emitting device, such as a light emitting diode (LED), is a device in which energy generated through electron-hole recombination in semiconductor junction parts is converted into light to be emitted therefrom. LEDs are commonly employed as light sources in illumination devices, display devices, and the like, and the development of LEDs has thus been accelerated.

In particular, recently, the development and employment of gallium nitride-based LEDs has increased. Mobile keypads, side viewers, camera flashes, and the like, using such gallium nitride-based LEDs, have been commercialized, and in line with this, the development of general illumination devices using LEDs has also accelerated. Like the products to which they are applied, such as a backlight unit of a large TV, a headlamp of a vehicle, a general illumination device, and the like, the purposes of LEDs are gradually moving from small portable products toward large-sized products having high output and high efficiency, and pertinent products require light sources that can support required characteristics thereof.

### SUMMARY

An aspect of the present general inventive concept provides a semiconductor light emitting device package and a method of manufacturing the same allowing for a reduction in manufacturing costs and time by solving problems of the related art semiconductor light emitting device realized as a wafer level package using through electrodes, such as a complicated manufacturing process, high manufacturing costs and prolonged manufacturing time.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a semiconductor light emitting device package including a base unit including a main body having electrical insulation properties and at least one pair of first and second through electrodes formed in the main body in a thickness direction thereof and formed of a semiconductor material, and a light emitting structure disposed on the base unit and including first and second conductivity type semiconductor layers and an active layer interposed there between.

Lateral surfaces of the main body and the light emitting structure may be coplanar.

The first and second through electrodes may have a metallic layer formed on surfaces thereof.

The first and second through electrodes may be formed of Si.

The main body may be formed of Si.

The main body may have a resistance value greater than that of the first and second through electrodes.

The foregoing and/or other features and utilities of the present general inventive concept may also be achieved by providing a method of manufacturing a semiconductor light emitting device package, the method including forming a light emitting structure by sequentially stacking a first conductivity type semiconductor layer, an active layer and a second conductivity type semiconductor layer on a substrate, and forming a base unit including at least one pair of first and second through electrodes electrically connected to the first and second conductivity type semiconductor layers, respectively, and formed of a semiconductor material, and a main body having electrical insulation properties.

The forming of the base unit may include forming first and second bonding layers on the first and second conductivity type semiconductor layers, respectively, and bonding an electrode substrate thereto, forming the first and second through electrodes on the first and second bonding layers, respectively, by processing the electrode substrate, and forming the main body by molding the first and second through electrodes with an electrically insulating material.

The electrically insulating material may be a thermoplastic resin or a thermosetting resin.

The forming of the base unit may include forming first and second bonding layers on the first and second conductivity type semiconductor layers, respectively, and bonding an electrode substrate thereto, forming the first and second through electrodes on the first and second bonding layers, respectively, by processing the electrode substrate, and forming the main body to have through holes therein and bonding the first and second through electrodes to the through holes.

The method may further include forming a metallic layer on surfaces of the first and second through electrodes before the forming of the main body.

The bonding of the first and second through electrodes to the through holes may be performed by filling an adhesive in the through holes or applying the adhesive to one of the surfaces of the first and second through electrodes.

The method may further include removing the substrate after the forming of the base unit.

Surfaces of the first and second through electrodes exposed after being bonded to the through holes may be covered by an under bump metallurgy (UBM) layer.

The bonding of the first and second through electrodes to the through holes may be performed by inserting the first and second through electrodes into the through holes and bonding the first and second through electrodes to the main body using a Si direct bonding method.

The foregoing and/or other features and utilities of the present general inventive concept may also be achieved by providing a semiconductor light emitting device package comprising a light-emitting structure having a first conductivity layer, a second conductivity layer and an active layer interposed there between, a lens unit attached to one side of the light-emitting structure, and a body attached to the other side of the light-emitting structure, the body including first and second electrodes connected to the first and second conductivity layers, respectively.

The first and second electrodes may be connected to the first and second conductivity layers via first and second bonding layers that reflect light from the active layer toward the lens unit.

The electrodes may comprise an insulator material coated with an electrode material.

The semiconductor light-emitting device package may further comprise a phosphor layer interposed between the lens unit and the light-emitting structure.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a schematic perspective view illustrating a semiconductor light emitting device package according to an exemplary embodiment of the present general inventive concept;

FIG. 2 is a cross-sectional view of the semiconductor light emitting device package of FIG. 1, taken along line A-A′;

FIG. 3 is a cross-sectional view illustrating a semiconductor light emitting device package according to another exemplary embodiment of the present general inventive concept; and

FIGS. 4 through 10 are schematic cross-sectional views illustrating a method of manufacturing the semiconductor light emitting device package of FIG. 1 according to an exemplary embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

The matters defined in the description, such as detailed construction and elements, are provided to assist in a comprehensive understanding of the exemplary embodiments. Thus, it is apparent that the exemplary embodiments can be carried out without those specifically defined matters. Also, functions or elements known in the related art are not described in detail since they would obscure the exemplary embodiments with unnecessary detail.

A method of manufacturing a semiconductor light emitting device package according to an exemplary embodiment of the present general inventive concept will now be provided. As shown in FIG. 4, a light emitting structure 120 is formed on a substrate 110.

The substrate 110 may be used for growing semiconductor single crystals, in particular, nitride single crystals. For example, a substrate formed of sapphire, Si, ZnO, GaAs, SiC, MgAl₂O₄, MgO, LiAlO₂, LiGaO₂, GaN or the like may be used therefor. Sapphire is a crystal having Hexa-Rhombo R3C symmetry and has a lattice constant of 13.001 Å along a C-axis and a lattice constant of 4.758 Å along an A-axis. Orientation planes of sapphire include a C (0001) plane, an A (1120) plane, an R (1102) plane, and the like. Particularly, the C plane is mainly used as a substrate for nitride semiconductor growth because it relatively facilitates the growth of a nitride film and is stable at high temperatures. Here, a semiconductor wafer may be used as the substrate 110.

The light emitting structure 120 may include a first conductivity type semiconductor layer 121, an active layer 122 and a second conductivity type semiconductor layer 123 sequentially stacked on the substrate 110.

The first conductivity type semiconductor layer 121 may be formed of group III-V nitride semiconductors. For example, the first conductivity type semiconductor layer 121 may be an n-GaN layer. The second conductivity type semiconductor layer 123 may be formed of group III-V nitride semiconductors. For example, the second conductivity type semiconductor layer 123 may be a p-GaN layer or a p-GaN/AlGaN layer.

The first conductivity type semiconductor layer 121 and the second conductivity type semiconductor layer 123 may be nitride semiconductor layers. The first conductivity type semiconductor layer 121 may include an n-type semiconductor layer and the second conductivity type semiconductor layer 123 may include a p-type semiconductor layer.

The n-type semiconductor layer and the p-type semiconductor layer may be formed of semiconductor materials doped with n-type and p-type impurities having a composition formula of AlₓIn_{y}Ga_{(1-x-y)}N, where 0≦x≦1, 0≦y≦1, and 0≦x+y≦1. As typical materials, GaN, AlGaN, and InGaN may be used.

The n-type impurities may include Si, Ge, Se, Te, C or the like, and the p-type impurities may include Mg, Zn, Be or the like.

In the present exemplary embodiment, GaN layers may be used as the first and second conductivity type semiconductor layers 121 and 123. The first conductivity type semiconductor layer may be formed of n-GaN, and the second conductivity type semiconductor layer may be formed of p-GaN.

The first and second conductivity type semiconductor layers 121 and 123 may be grown by metal organic chemical vapor deposition (MOCVD), molecular beam epitaxy (MBE), hydride vapor phase epitaxy (HVPE) or the like.

The active layer 122 may have a multi-quantum-well (MQW) structure in which quantum well layers and quantum barrier layers are alternately stacked. For example, the active layer 122 may have a multi-quantum-well (MQW) structure in which quantum well layers and quantum barrier layers formed of AlₓIn_{y}Ga_{1-x-y}N (0≦x≦1, 0≦y≦1, and 0≦x+y≦1) are alternately stacked, such that it may have a predetermined energy bandgap and emit light through electron-hole recombination. The active layer 122 may emit visible light having a wavelength range of approximately 350 nm to 680 nm. The active layer 122 may be grown in the same manner as the first and second conductivity type semiconductor layers 121 and 123 by using MOCVD, MBE or the like.

Next, as shown in FIG. 5, the active layer 122 and the second conductivity type nitride semiconductor layer 123 may be partially removed from the light emitting structure 120 to thereby expose a portion 124 of an upper surface of the first conductivity type nitride semiconductor layer 121 and form a mesa-surface.

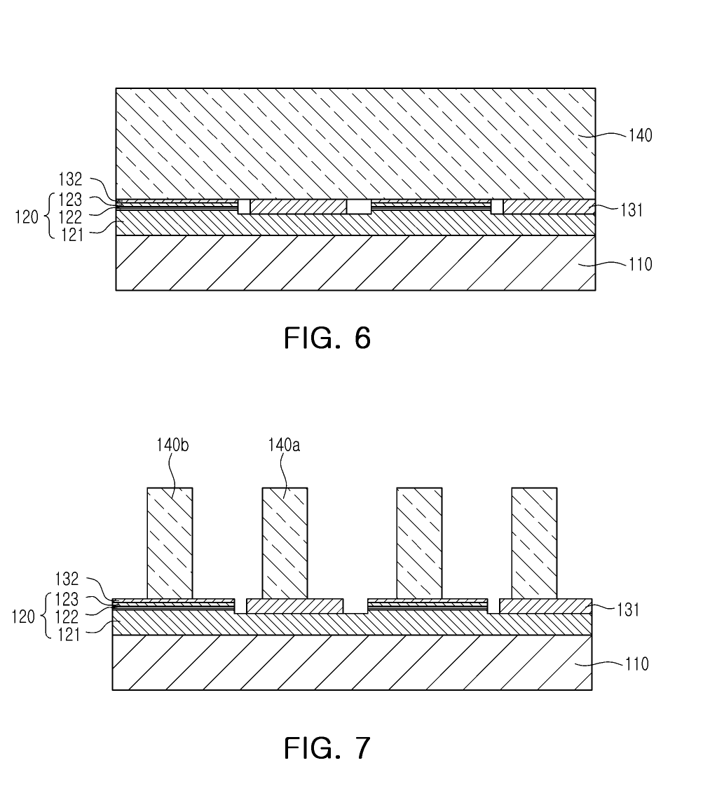

Thereafter, as shown in FIG. 6, first and second bonding layers 131 and 132 may be formed on the first and second conductivity type semiconductor layers 121 and 123, respectively, and an electrode substrate 140 may be attached thereto. The electrode substrate 140 may be formed of a semiconductor material. In the present embodiment, the electrode substrate 140 may be formed of Si.

The first and second bonding layers 131 and 132 may be used as adhesive layers for bonding the electrode substrate 140 to the first and second conductivity type semiconductor layers 121 and 123. The first and second bonding layers 131 and 132 may be formed of metallic materials such as Au, Al, Ag and the like, and may have a multilayer structure including two or more layers. The first and second bonding layers 131 and 132 may be disposed below the active layer 122, such that they reflect light emitted from the active layer 122 to thereby allow the light to be emitted to the exposed surface of the first conductivity type semiconductor layer 121, whereby external light extraction efficiency may be further improved.

As shown in FIG. 7, the electrode substrate 140 may be used to form first and second through electrodes 140a and 140b electrically connected to the first and second bonding layers 131 and 132, respectively, for supplying power. A metallic layer (not illustrated) may further be formed on surfaces of the first and second through electrodes 140a and 140b, such that it may further improve electrical conductivity of the first and second through electrodes 140a and 140b.

The metallic layer may be formed to cover the surfaces of the first and second through electrodes 140a and 140b. The metallic layer may be formed as a single layer or multiple layers formed of a metal selected from the group consisting of Ni, Au, Ag, Ti, Cr and Cu. In addition, the metallic layer may be formed by a deposition method known in the art such as a chemical vapor deposition (CVD) and an e-beam evaporation, a sputtering method or the like.

The first and second through electrodes 140a and 140b may be formed by processing the electrode substrate 140 using a micromechanical process such as Microelectromechanical Systems (MEMS). At least one first through electrode 140a and at least one second through electrode 140b may be respectively formed on the first and second bonding layers 131 and 132, such that they receive power supplied thereto through the first and second bonding layers 131 and 132.

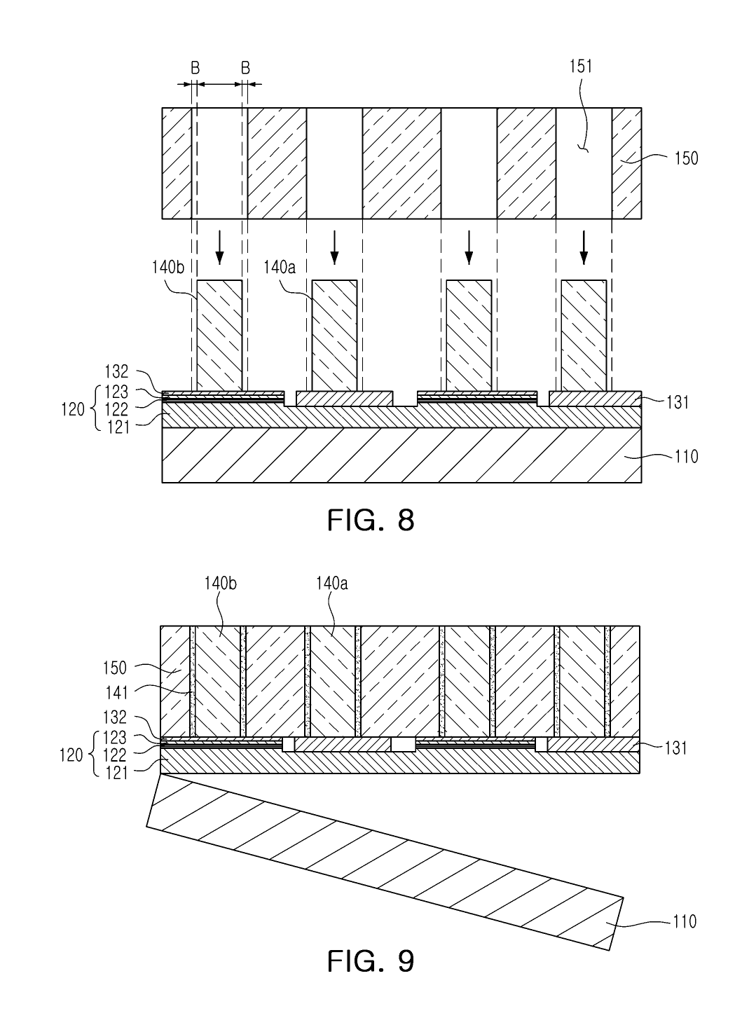

As shown in FIG. 8, first and second through electrodes 140a and 140b may have a size sufficient to be inserted into through holes 151 of a main body 150. In consideration of manufacturing errors or the optional metallic layer additionally deposited thereon, the first and second through electrodes 140a and 140b may have a size sufficient to be inserted into the through holes 151, while having predetermined gaps B with the through holes 151.

According to the related art, through holes are formed in a substrate and through electrodes are formed in the through holes using a plating process that consumes a considerable amount of manufacturing time. In particular, since the through holes are formed as elongated microtubes, plating the through holes with metal may require a lot of time, and a void may be formed inside the through holes.

In the embodiment of the present general inventive concept, the first and second through electrodes 140a and 140b previously formed, instead of the plating process, may be inserted into the through holes 151, and thus manufacturing time may be reduced as compared with the related art method, and the formation of the void may be avoided. In addition, such a complicated plating process is not performed, so that the manufacturing process may be simplified and manufacturing costs may be reduced.

Then, as further shown in FIG. 8, the main body 150 having the through holes 151 formed therein may be combined with the first and second through electrodes 140a and 140b, thereby forming a base unit.

The main body 150 having the through holes 151 formed therein may be obtained by forming a plate with an electrically insulating material and forming the through holes 151 in a thickness direction thereof. The main body 150 may be formed of various materials such as a metallic substrate or a semiconductor substrate processed to be insulated, an insulating substance such as a synthetic resin, or the like. The main body 150 may be formed, for example, by injecting a synthetic resin into a mold having a shape corresponding to that of the main body 150. Alternatively, the main body 150 may be formed by processing an upper surface of a metallic substrate through molding, milling or laser processing, and insulating the surface of the metallic substrate. Alternatively, the main body 150 may be formed of a semiconductor substrate such as a Si substrate.

The through holes 151 may be positioned to correspond to the positions of the first and second through electrodes 140a and 140b while having a size allowing the first and second through electrodes 140a and 140b to be inserted thereinto.

The combining of the main body 150 and the first and second through electrodes 140a and 140b may be performed by fitting the first and second through electrodes 140a and 140b into the through holes 151. Alternatively, at least one of the surfaces of the through holes 151 of the main body 150 or the first and second through electrodes 140a and 140b may be filled with an adhesive or have an adhesive applied thereto such that the first and second through electrodes 140a and 140b may be bonded to the through holes 151. When the first and second through electrodes 140a and 140b are bonded to the through holes 150, the adhesive may fill the gaps B between the main body 150 and the first and second through electrodes 140a and 140b, for example, by a capillary phenomenon, thereby allowing them to be firmly bonded to each other. Here, the adhesive may include one of an epoxy resin, a silicone resin, a ceramic compound, and a glass (SiO₂) compound.

In addition, the bonding of the main body 150 and the first and second through electrodes 140a and 140b may be performed by an underfill process allowing an adhesive such as a resin or the like to be injected into the gaps B between the main body 150 and the first and second through electrodes 140a and 140b by a capillary phenomenon after the main body 150 and the first and second through electrodes 140a and 140b are combined with each other.

Alternatively, an adhesive may be applied to bonding surfaces between the main body 150 and the first and second through electrodes 140a and 140b, and the adhesive-applied surfaces may be bonded to each other.

Alternatively, the main body 150 and the first and second through electrodes 140a and 140b may be formed of Si, and the main body 150 and the first and second through electrodes 140a and 140b may be bonded to each other by a Si direct bonding (SDB) method.

The SDB method allows two semiconductor substrates for mounting electronic devices to be bonded by a heat treatment without an adhesive. Since an adhesive layer is not formed, a module or a process for the formation and removal of the adhesive layer is not required. Accordingly, processing costs and time may be reduced.

The bonding of the main body 150 and the first and second through electrodes 140a and 140b may be implemented by growing a bonding layer 141 there between through heat treatment. The bonding layer 141 in the embodiment of the present general inventive concept may be a SiO₂ layer. The SiO₂ layer may be grown to fill the gaps between the main body 150 and the first and second through electrodes 140a and 140b.

As further shown in FIG. 8, the gaps B between the main body 150 and the first and second through electrodes 140a and 140b may be within a range in which the SiO₂ layer can be formed by heat treatment. Specifically, the gaps B may be within a range of 10 μm or less.

In the case in which the main body 150 and the first and second through electrodes 140a and 140b are bonded to each other by the SDB method, the SiO₂ layer may only be grown between the through holes 151 of the main body 150 and the first and second through electrodes 140a and 140b, and thus the SiO₂ insulating layer is not grown on an upper surface of the main body exposed above the through holes 151. In addition, when a resistance value of the main body 150 is greater than that of the first and second through electrodes 140a and 140b, the main body 150 may function as an electrical insulator. The resistance values of the main body 150 and the first and second through electrodes 140a and 140b may be controlled by adjusting the concentration of impurities doped therein. The resistance values of the main body 150 and the first and second through electrodes 140a and 140b are not limited to specific values, so long as they may be within a range allowing only the first and second through electrodes 140a and 140b to function as conductors by determining a value of current flowing in the main body 150 within a range able to be disregarded as compared to a value of current flowing in the first and second through electrodes 140a and 140b.

As shown in FIG. 9, when the main body 150 and the first and second through electrodes 140a and 140b are bonded to each other, the metallic layer formed on end portions of the first and second through electrodes 140a and 140b or surfaces of the first and second through electrodes 140a and 140b may be exposed.

The base unit may function as a support for supporting the light emitting structure 120 during a separation process, such as a laser lift off (LLO) process or the like for separating the substrate 110 from the light emitting structure 120. Accordingly, after the formation of the base unit, the substrate 110 may be separated from the light emitting structure 120.

A laser used in the LLO process may be at least one of an excimer laser having a wavelength of 193 nm, 248 nm, or 308 nm, a Nd:YAG laser, a He—Ne laser and an Ar ion laser.

Alternatively, the substrate 110 may be removed by a physical method such as grinding, polishing, lapping or the like. A portion of the substrate 110 may be removed to thereby reduce a thickness of the substrate 110.

The separation of the substrate 110 may be performed for reducing a size of the semiconductor light emitting device package 100 by reducing the thickness of the substrate 110 included therein and improving heat emission performance. The separation of the substrate 110 may be performed on the exposed surface of the substrate 110. The separation of the substrate 110 may not be essentially required, and may be omitted in the case in which the substrate 110 is originally thin.

When the base unit is formed on the light emitting structure 120, the light emitting structure 120 is bonded to the base unit, for example, in a flip-chip structure. Therefore, when power is applied to the first and second through electrodes 140a and 140b, light generated in the active layer 122 is emitted through the exposed surface of the first conductivity type semiconductor layer 121.

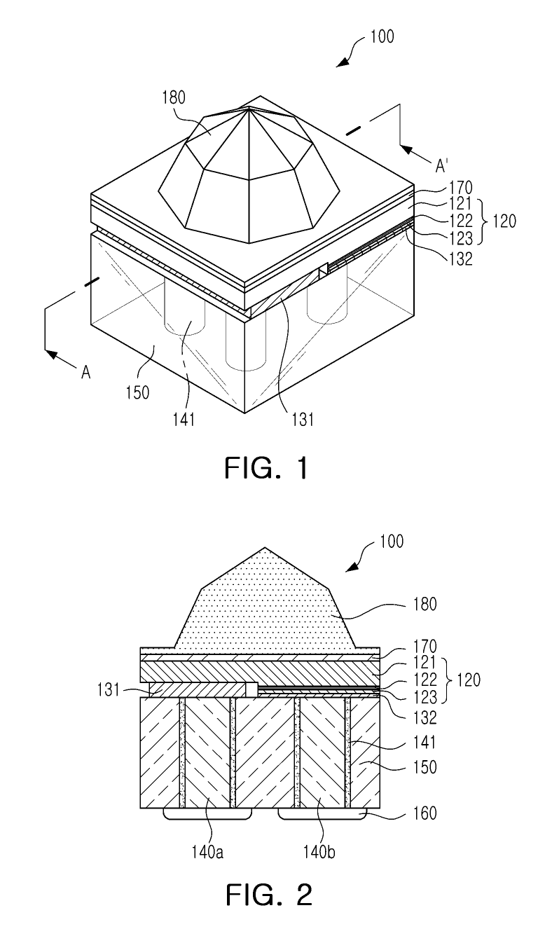

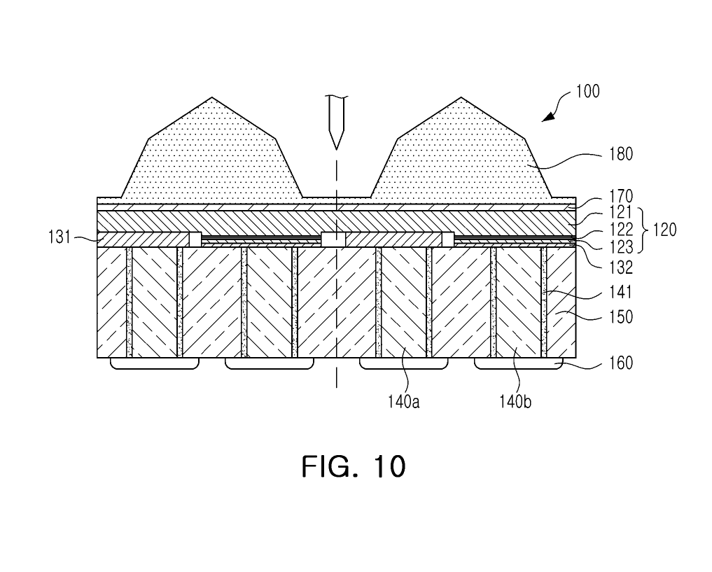

As shown in FIG. 10, a phosphor layer 170 and a lens unit 180 may be further formed on the surface of the light emitting structure 120. First and second through electrodes 140a and 140b may be capped with contacts 160. After a breaking process for division into individual semiconductor light emitting device packages, the semiconductor light emitting device package 100 as shown in FIGS. 1 and 2 may be manufactured. In this manner, the light emitting structure 120 and the main body 150 are simultaneously cut in a single process, such that lateral surfaces of the light emitting structure 120 and the main body 150 are coplanar.

In the semiconductor light emitting device package 100, the first and second through electrodes 140a and 140b are formed directly on the light emitting structure 120 and the main body 150 formed of an insulating material is directly bonded thereto, such that a wafer level package (WLF) allowing the light emitting structure 120 to be formed as a package may be achieved.

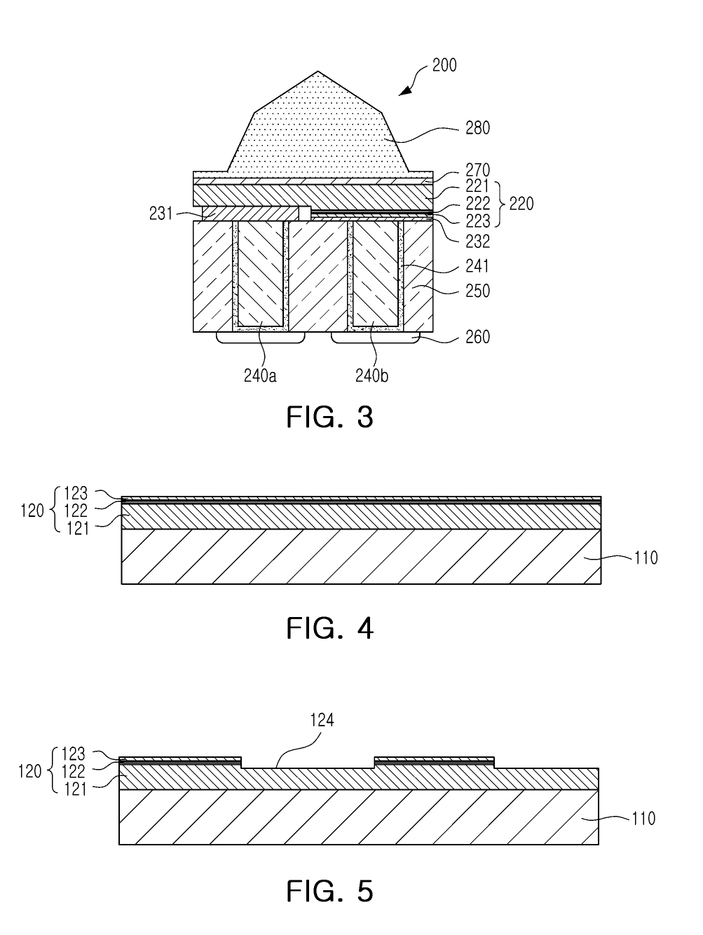

As shown in FIG. 3, a semiconductor light emitting device package 200 according to another embodiment of the present general inventive concept, including a lens unit 280, phosphor layer 270, first and second bonding layers 231 and 232, contacts 260, and light-emitting layer 220 comprising active layer 222 and first and second conductive layers 221 and 223. Semiconductor light emitting device package 200 may allow first and second through electrodes 240a and 240b to be coated with an electrode material 241 and inserted into a main body 250.

In the case of coating the electrode material 241 on the surfaces of the first and second through electrodes 240a and 240b, the first and second through electrodes 240a and 240b can be formed of an insulator such as a synthetic resin, whereby a manufacturing process may be simplified.

The semiconductor light emitting device package 200 is similar to the semiconductor light emitting device package 100, however, the main body 250 in the semiconductor light emitting device package 200 may be formed by molding the first and second through electrodes 240a and 240b with an electrically insulating material, unlike the main body 150 in the semiconductor light emitting device package 100 that is formed in advance and is then combined with the first and second through electrodes 140a and 140b.

The main body 250 may be formed, for example, by placing the first and second through electrodes 240a and 240b in a mold having a shape corresponding to that of the main body 250 and injecting the electrically insulating material into the mold while covering the surfaces of the first and second through electrodes 240a and 240b with the electrically insulating material. In this case, a thermoplastic resin or a thermosetting resin may be used as the electrically insulating material.

In the case in which the main body 250 is formed by molding the first and second through electrodes 240a and 240b with the electrically insulating material, there is no need to form through holes in the main body 250. In addition, adhesion between the first and second through electrodes 240a and 240b and the main body 250 may be increased, gaps there between may be reduced. Accordingly, the strength of the package may be improved and manufacturing process may be simplified.

As set forth above, according to embodiments of the present general inventive concept, a semiconductor light emitting device package and a method of manufacturing the same may be implemented by simplified manufacturing process, thereby achieving a reduction in manufacturing costs and time.

While the present general inventive concept has been shown and described in connection with the embodiments, it will be apparent to those skilled in the art that modifications and variations can be made without departing from the spirit and scope of the general inventive concept as defined by the appended claims and their equivalents.

What is claimed is:

1. A semiconductor light emitting device package comprising:
a base unit including a main body having electrical insulation properties and at least one pair of first and second through electrodes formed in the main body in a thickness direction thereof and formed of a semiconductor material; and
a light emitting structure disposed on the base unit and including first and second conductivity type semiconductor layers and an active layer interposed there between.

2. The semiconductor light emitting device package of claim 1, wherein lateral surfaces of the main body and the light emitting structure are coplanar.

3. The semiconductor light emitting device package of claim 1, wherein the first and second through electrodes have a metallic layer formed on surfaces thereof.

4. The semiconductor light emitting device package of claim 1, wherein the first and second through electrodes are formed of Si.

5. The semiconductor light emitting device package of claim 4, wherein the main body is formed of Si.

6. The semiconductor light emitting device package of claim 5, wherein the main body has a resistance value greater than that of the first and second through electrodes.

7. A method of manufacturing a semiconductor light emitting device package, the method comprising:
forming a light emitting structure by sequentially stacking a first conductivity type semiconductor layer, an active layer and a second conductivity type semiconductor layer on a substrate; and
forming a base unit including at least one pair of first and second through electrodes electrically connected to the first and second conductivity type semiconductor layers, respectively, and formed of a semiconductor material and a main body having electrical insulation properties.

8. The method of claim 7, wherein the forming of the base unit includes:
forming first and second bonding layers on the first and second conductivity type semiconductor layers, respectively, and bonding an electrode substrate thereto;
forming the first and second through electrodes on the first and second bonding layers, respectively, by processing the electrode substrate; and
forming the main body by molding the first and second through electrodes with an electrically insulating material.

9. The method of claim 8, wherein the electrically insulating material is a thermoplastic resin or a thermosetting resin.

10. The method of claim 7, wherein the forming of the base unit includes:
forming first and second bonding layers on the first and second conductivity type semiconductor layers, respectively, and bonding an electrode substrate thereto;
forming the first and second through electrodes on the first and second bonding layers, respectively, by processing the electrode substrate; and
forming the main body to have through holes therein and bonding the first and second through electrodes to the through holes.

11. The method of claim 7, further comprising forming a metallic layer on surfaces of the first and second through electrodes before the forming of the main body.

12. The method of claim 10, wherein the bonding of the first and second through electrodes to the through holes is performed by filling an adhesive in the through holes or applying the adhesive to one surfaces of the first and second through electrodes.

13. The method of claim 7, further comprising removing the substrate after the forming of the base unit.

14. The method of claim 10, wherein surfaces of the first and second through electrodes exposed after being bonded to the through holes are covered by an under bump metallurgy (UBM) layer.

15. The method of claim 10, wherein the bonding of the first and second through electrodes to the through holes is performed by inserting the first and second through electrodes into the through holes and bonding the first and second through electrodes to the main body using a Si direct bonding method.

16. A semiconductor light emitting device package comprising:
a light emitting structure having a first conductivity layer, a second conductivity layer and an active layer interposed there between;
a lens unit attached to one side of the light emitting structure; and
a body attached to the other side of the light emitting structure, the body including first and second electrodes connected to the first and second conductivity layers, respectively.

17. The semiconductor light emitting device package of claim 16, wherein the active layer has a multi-quantum-well structure.

18. The semiconductor light emitting device package of claim 16, wherein the first and second electrodes are connected to the first and second conductivity layers via first and second bonding layers that reflect light from the active layer toward the lens unit.

19. The semiconductor light emitting device package of claim 16, wherein the electrodes comprise an insulator material coated with an electrode material.

20. The semiconductor light emitting device package of claim 16, further comprising a phosphor layer interposed between the lens unit and the light emitting structure.
